(19) United States
(12) Patent Application Publication
(10) Pub. No.: US 2023/0207225 A1
(43) Pub. Date: Jun. 29, 2023

(54) COMPOSITION FOR FORMING HOLE TRANSPORT LAYER OF LIGHT-TRANSMITTING SOLAR CELL AND METHOD FOR MANUFACTURING LIGHT-TRANSMITTING SOLAR CELL

(71) Applicants: Hyundai Motor Company, Seoul (KR); Kia Corporation, Seoul (KR); Korea University Research and Business Foundation, Seoul (KR)

(72) Inventors: Yeong Hee Lee, Gwacheon (KR); Young Chan Kim, Seoul (KR); Ri Ra Kang, Uiwang (KR); Byung Hong Lee, Suwon (KR); Kyoung Han Ryu, Yongin (KR); Young Suk Cho, Sejong (KR); Jun Hong Noh, Seoul (KR); Min Ju Jeong, Seoul (KR); Jun Hyeok Lee, Seoul (KR); Chang Hyuk You, Seoul (KR)

(21) Appl. No.: 17/985,872

(22) Filed: Nov. 13, 2022

(30) Foreign Application Priority Data
Dec. 10, 2021 (KR) 10-2021-0176548

(51) Int. Cl. H01G 9/20; H01G 9/00; H10K 30/30; H10K 30/40; H10K 30/82; H10K 71/15; H10K 71/40; H10K 85/50

(52) U.S. Cl. CPC H01G 9/2009; H01G 9/0036; H10K 30/30; H10K 30/40; H10K 30/82; H10K 71/15; H10K 71/441; H10K 85/50

(57) ABSTRACT

Disclosed are a composition for forming a hole transport layer of a light-transmitting solar cell, a method for manufacturing the light-transmitting solar cell, and a light-transmitting solar cell manufactured thereby. The light-transmitting solar cell manufactured with the composition for forming the hole transport layer may have excellent durability and therefore, not only deposit a transparent electrode, which is an upper electrode, without damage even without buffer layer, thereby reducing the process cost but also deposit the transparent electrode without damage by using a general sputter equipment even without using an expensive special sputter equipment.

### CROSS REFERENCE TO RELATED APPLICATION

This application claims under 35 U.S.C. §119(a) the benefit of priority to Korean Patent Application No. 10-2021-0176548 filed on Dec. 10, 2021, the entire contents of which are incorporated herein by reference.

### TECHNICAL FIELD

The present disclosure relates to a composition for forming a hole transport layer of a light-transmitting solar cell, a method for manufacturing the light-transmitting solar cell, and a light-transmitting solar cell manufactured thereby.

### BACKGROUND

An upper electrode of the conventional solar cell uses an opaque upper electrode, but the upper electrode should also be transparent so that light may transmit to reach heterojunction cells, and recently, a method for replacing the upper electrode with a transparent electrode is being performed.

In the related art, the upper electrode may be formed on a hole transport layer in a sputtering method when the upper electrode is formed of the transparent electrode. However, the hole transport layer including an organic material may have weak durability, and therefore, the hole transport layer may be damaged during the manufacturing process in the process of depositing the transparent electrode. For example, efforts have been made to reduce durability damage by separately adding a buffer layer, however, process efficiency is reduced due to the additional process and poor stability of the solar cell because of the low heat resistance of the buffer layer.

In addition, a light-transmitting solar cell in which the upper electrode is formed of the transparent electrode has a problem in that photoelectric conversion efficiency is also reduced.

The above information disclosed in this Background section is only for enhancement of understanding of the background of the disclosure and accordingly it may include information that does not form the prior art that is already known in this country to a person of ordinary skill in the art.

### SUMMARY

In preferred aspects, provided are a composition for forming a hole transport layer of a light-transmitting solar cell including a metal oxide-based hole transport material and a solvent component, a method for manufacturing the light-transmitting solar cell by using the same, and the light-transmitting solar cell manufactured by the manufacturing method and including the hole transport layer including the metal oxide-based hole transport material.

In an aspect, provided is a composition for forming a hole transport layer of a light-transmitting solar cell may include: a metal oxide-based hole transport material; and a solvent component. In certain embodiments, the solvent component may be, or consist of a single solvent.

The term “light-transmitting solar cell” as used herein refers to a cell unit or power generator unit that can convert light (solar) energy, e.g., visible or UV light, into electric energy, which is mediated by compounds or materials having hole-transport characteristic.

The term “hole transport material” as used herein a material having one or more electron holes (“holes”) in its molecular structure or crystal structure by lacking one or more electrons, e.g., at a position of lattice points. The hole transport material may have one or more electron holes where a metal atom or a semiconducting atom lacks electrons in the lattice structure. In a solar cell, light-generating holes transfer from the light-absorbing layer into the hole transport material.

The light-absorbing materials may be a perovskite-structured compound having a crystal structure such as ABX₃ where A and B are cations and X is an anion. Exemplary perovskite-structured compound may be a hybrid organic-inorganic metal-halide based material, e.g., a hybrid organic-inorganic lead or tin halide-based material, or methylammonium lead trihalide.

The term “metal oxide” as used herein refers to a compound including a metal component (e.g., alkali metals, alkali earth metals, or transition metals) combined with one or more oxygen atoms. The metal oxide may be formed by stable chemical bonds between the metal and the oxygen atoms. Exemplary metals in preferred embodiments may include one or more trnasition metals, particularly, nickel (Ni), copper (Cu), vanadium (V), chromium (Cr), and tungsten (Tu).

The metal oxide-based hole transport material may include one or more selected from the group consisting of a nickel oxide-based hole transport material, a copper oxide-based hole transport material, a vanadium oxide-based hole transport material, a chromium oxide-based hole transport material, and a tungsten oxide-based hole transport material.

The metal oxide-based hole transport material may include one or more selected from the group consisting ofNiOₓ (1≤x≤2), Cu₂O, CuO, CuGaO₂, CuCrO₂, VO₂, CrO₂, and WO₃.

The solvent component may include one selected from the group consisting of alcohols in which a hydrogen bonding index is about 13 MPa^{½} or less and the number of carbon atoms of an alkyl group is 6 or greater.

The alcohol may be selected from the group consisting of hexanol, heptanol, octanol, nonanol, decanol, undecanol, dodecanol, tetradecanol, pentadecanol, hexadecanol, and octadecanol.

The concentration of the composition for forming the hole transport layer of the light-transmitting solar cell may be about 1 mg/mL to 100 mg/mL.

In an aspect, provided is a method for manufacturing a light-transmitting solar cell including: preparing a first transparent electrode; forming an electron transport layer on the first transparent electrode; forming a light absorption layer including a compound having a perovskite structure on the electron transport layer; forming a hole transport layer on the light absorption layer; and forming a second transparent electrode on the light absorption layer. The hole transport layer may include a composition including a metal oxide-based hole transport material and a solvent component.

The forming of the hole transport layer may include applying the composition on the light absorption layer; and heat-treating the applied composition.

The forming of the hole transport layer may be performed at the temperature of about 150° C. or less for about 45 seconds to 55 seconds.

The applied composition may be heat treated at the temperature of about 110° C. to 130° C. for about 5 minutes to 15 minutes.

In an aspect, provided is a light-transmitting solar cell including: a first transparent electrode; an electron transport layer formed on the first transparent electrode; a light absorption layer formed on the electron transport layer; a hole transport layer formed on the light absorption layer; and a second transparent electrode formed on the hole transport layer. The hole transport layer may include a metal oxide-based hole transport material. The composition densely and uniformly formed on the light absorption layer has a coverage of about 90% or greater on the surface of the light absorption layer per 10 × 10 µm² unit area, and the deviation of the thicknesses of the thin film at various random points may be less than about 20%.

The thickness of the hole transport layer may be about 10 nm to 200 nm.

The light-transmitting solar cell may have a transmittance of about 50% or greater.

The light-transmitting solar cell manufactured with the composition for forming the hole transport layer of the light-transmitting solar cell according to various exemplary embodiments of the present disclosure may include the hole transport layer including the metal-oxide-based hole transport material and therefore, have the excellent durability unlike the hole transport layer made of the organic material, thereby not only reducing the process cost by depositing the transparent electrode that is the upper electrode without damage even without the buffer layer but also depositing the transparent electrode without damage by using the general sputter equipment even without using the expensive special sputter equipment.

In addition, the composition for forming the hole transport layer of the light-transmitting solar cell according to various exemplary embodiments of the present disclosure may include the single solvent component and therefore, the hole transport layer capable of having the large area due to having densification and uniformity even at the low temperature may be manufactured by using the composition, thereby not lowering the photoelectric conversion efficiency of the light-transmitting solar cell including the same.

Also provided herein is a vehicle including the light-transmitting solar cell as described herein.

The above and other features of the disclosure are discussed infra.

### BRIEF DESCRIPTION OF THE DRAWINGS

The above and other features of the present disclosure will now be described in detail with reference to certain exemplary examples thereof illustrated in the accompanying drawings which are given herein below by way of illustration only, and thus are not limitative of the present disclosure, and wherein:

FIG. 1 shows a current density-voltage curve according to light scan directions (forward vs. reverse) of solar cells according to Comparative Examples 2-1 and 2-2 of the present disclosure.

FIG. 2 shows a current density-voltage curve according to light scan directions (forward vs. reverse) of solar cells according to Example 2 and Comparative Example 1-2 of the present disclosure.

FIG. 3 shows a current density-voltage curve according to light scan directions (forward vs. reverse) of solar cells according to Example 1 and Comparative Example 1-1 of the present disclosure.

FIG. 4 shows a current density-voltage curve according to light scan directions (forward vs. reverse) of solar cells according to Comparative Examples 3-1 and 3-2 of the present disclosure.

FIG. 5 shows transmittance measurement results of the solar cells according to Example 1 and Comparative Example 1-1.

FIG. 6 shows an image from a scanning electron microscope (SEM) showing a surface coverage of a light absorption layer of a hole transport layer finally manufactured with the composition produced according to Manufacturing Example 2.

FIG. 7 shows a cross-sectional image of a scanning electron microscope (SEM) showing a thin film thickness (uniformity) of the hole transport layer finally formed on the light absorption layer with the composition produced according to Manufacturing Example 2.

It should be understood that the appended drawings are not necessarily to scale, presenting a somewhat simplified representation of various preferred features illustrative of the basic principles of the disclosure. The specific design features of the present disclosure as disclosed herein, including, for example, specific dimensions, orientations, locations, and shapes will be determined in section by the particular intended application and use environment.

In the figures, reference numbers refer to the same or equivalent sections of the present disclosure throughout the several figures of the drawing.

### DETAILED DESCRIPTION

The above objects, other objects, features, and advantages of the present disclosure will be readily understood through the following preferred exemplary embodiments related to the accompanying drawings. However, the present disclosure is not limited to the exemplary embodiments described herein and may also be specified in other forms. Rather, the exemplary embodiments described herein are provided so that the disclosed contents can be thorough and complete and the technical spirit of the present disclosure may be sufficiently conveyed to those skilled in the art.

Similar reference numerals have been used for similar components while describing each drawing. In the accompanying drawings, the dimensions of the structures are shown larger than those of the real ones for the clarity of the present disclosure. The terms first, second, etc. may be used to describe various components, but the components should not be limited to the above terms. The terms are used only for the purpose of distinguishing one component from another. For example, a first component may be named as a second component without departing from the scope of the present disclosure, and similarly, the second component may also be named as the first component. The singular expression includes a plurality of expressions unless the context clearly mean otherwise.

In the present specification, it should be understood that the term “include” or “have” is intended to specify the presence of features, numbers, steps, operations, components, parts or combinations thereof described in the specification, and does not preclude the possibility of the presence or addition of one or more other features or numbers, steps, operations, components, parts or combinations thereof in advance. In addition, if a portion such as a layer, a membrane, a region, or a plate is said to be “on” another portion, this includes not only a case where it is “directly above” another portion, but also a case where it has other parts interposed therebetween. Conversely, if a portion such as a layer, a membrane, a region, or a plate is said to be “under” another portion, this includes not only a case where it is “directly under” another portion, but also a case where it has other portions interposed therebetween.

Unless otherwise specified, since all numbers, values, and/or expressions representing components, reaction conditions, polymer compositions, and an amount of mixtures used in the present specification are approximations reflecting various uncertainties of measurements that these numbers essentially occur in obtaining these values from the others, it should be understood that all cases are modified by the term “about”.

Further, unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

In addition, if the numerical range is disclosed in the present disclosure, this range is continuous, and includes all values from the minimum value to the maximum value in this range unless indicated otherwise. Furthermore, if this range refers to an integer, all integers including the minimum value to the maximum value are included unless otherwise indicated. In the present specification, when a range is described for a variable, it will be understood that the variable includes all values including the end points described within the stated range. For example, the range of “5 to 10” will be understood to include any subranges, such as 6 to 10, 7 to 10, 6 to 9, 7 to 9, and the like, as well as individual values of 5, 6, 7, 8, 9 and 10, and will also be understood to include any value between valid integers within the stated range, such as 5.5, 6.5, 7.5, 5.5 to 8.5, 6.5 to 9, and the like. Also, for example, the range of “10% to 30%” will be understood to include subranges, such as 10% to 15%, 12% to 18%, 20% to 30%, etc., as well as all integers including values of 10%, 11%, 12%, 13% and the like up to 30%, and will also be understood to include any value between valid integers within the stated range, such as 10.5%, 15.5%, 25.5%, and the like.

It is understood that the term “automotive” or “vehicular” or other similar term as used herein is inclusive of motor automotives in general such as passenger automobiles including sports utility automotives (operation SUV), buses, trucks, various commercial automotives, watercraft including a variety of boats and ships, aircraft, and the like, and includes hybrid automotives, electric automotives, plug-in hybrid electric automotives, hydrogen-powered automotives and other alternative fuel automotives (e.g., fuels derived from resources other than petroleum). As referred to herein, a hybrid automotive is an automotive that has two or more sources of power, for example both gasoline-powered and electric-powered automotives.

When a hole transport layer for a conventional perovskite type solar cell includes the hole transport material based on the organic material, the hole transport layer has weak durability. Further, the hole transport layer is damaged during the manufacturing process in the process of depositing the transparent electrode, and therefore, efforts have been made to reduce durability damage by applying the buffer layer. However, the stability of the solar cell may be reduced as well as process efficiency due to the additional process, and the light-transmitting solar cell forming the upper electrode with the transparent electrode also has the reduced photoelectric conversion efficiency.

In an aspect, provided is a light-transmitting solar cell including the hole transport layer manufactured by using the composition for forming the hole transport layer of the light-transmitting solar cell including the metal-oxide-based hole transport material and the single solvent, which has the excellent durability unlike the hole transport layer made of the organic material. As such, the process cost may be reduced by depositing the transparent electrode that is the upper electrode without damage even without the buffer layer but also the transparent electrode may be deposited without damage by using the general sputter equipment even without using the expensive special sputter equipment. In addition, the photoelectric conversion efficiency of the light-transmitting solar cell including the dense and uniform hole transport layer manufactured with the composition for forming the hole transport layer including the single solvent may be excellent.

A composition for forming a hole transport layer of a light-transmitting solar cell may include a metal oxide-based hole transport material; and a solvent component. The solvent component may consist of a single solvent.

The hole transport material may be positioned between a perovskite layer and a second transparent electrode based on a normal type (n-i-p) to transport the holes provided from the perovskite layer to the second transparent electrode, and may exist on the hole transport layer.

Among them, the metal oxide-based hole transport material may be a metal oxide formed by oxidizing a specific metal and is a material capable of hole transport and for example, may include one or more selected from the group consisting of a nickel oxide-based hole transport material, a copper oxide-based hole transport material, a vanadium oxide-based hole transport material, a chromium oxide-based hole transport material, and a tungsten oxide-based hole transport material, and preferably include one or more selected from the group consisting of NiOₓ (1≤x≤2), Cu₂O, CuO, CuGaO2, CuCrO₂, VO₂, CrO₂, and WO₃, and preferably include NiOₓ (1≤x≤2) having excellent charge mobility and low electron affinity without additives.

Since the composition for forming the hole transport layer may include the metal oxide-based hole transport material and therefore, the hole transport layer may be finally manufactured, the durability may be excellent, thereby not only reducing the process cost by depositing the transparent electrode that is the upper electrode without damage even without the buffer layer but also depositing the transparent electrode without damage by using the general sputter equipment even without using the expensive special sputter equipment.

In addition, the composition for forming the hole transport layer may generally further include a solvent component for dispersing the hole transport material, and for example, may include one or more selected from the group consisting of n-alkyl sulfide, aniline, pyridine, thiophenol, thiophenoxide, phenanthroline, ortho-benzenediamine, and thiocatechol, and conventionally, a mixed solvent in which two or more types are mixed is mainly used to produce the composition for forming the hole transport layer that minimizes damage to the upper portion of a photoactive layer and has a high dispersion.

Preferably, the composition for forming the hole transport layer may include, or consist ofa single solvent, and therefore, the hole transport layer capable of having the large area due to having densification and uniformity even at the low temperature may be manufactured by using the composition.

The single solvent used in the composition for forming the hole transport layer may include, or consist of, for example, one selected from the group consisting of alcohols to produce the composition in which the metal oxide-based hole transport material may be highly dispersed, preferably, include one selected from the group consisting of hexanol, heptanol, octanol, nonanol, decanol, undecanol, dodecanol, tetradecanol, pentadecanol, hexadecanol, and octadecanol. The single solvent may be an alcohol having hydrophobicity in which the hydrogen bonding index of the single solvent is about 13 MPa^{½} or less and the number of carbon atoms in the alkyl group constituting the alcohol compound is 6 or greater because the hydrogen bonding index is one of the important factors in dispersing the metal oxide-based hole transport material in the single solvent. Particularly, the single solvent may be hexanol or octanol that is the single solvent considering the vapor pressure at which the solvent may be evaporated during a heat treatment process after the thin film is coated among the alcohols.

In addition, the concentration of the composition for forming the hole transport layer of the light-transmitting solar cell may be about 1 mg/mL to 100 mg/mL. The concentration means a concentration of the metal oxide-based hole transport material in the single solvent. When the concentration is less than the above range, e.g., less than about 1 mg/mL, it is difficult to form a dense thin film due to insufficient coverage when the thin film of the hole transport layer is formed. When the concentration is is greater than the above range, e.g., greater than about 100 mg/mL, the thick thin film of the hole transport layer is formed and a series resistance increases, leading to the degradation of device performance.

In an aspect, a method for manufacturing a light-transmitting solar cell may include preparing a first transparent electrode; forming an electron transport layer on the first transparent electrode; forming a light absorption layer including a compound of a perovskite structure on the electron transport layer; forming a hole transport layer on the light absorption layer; and forming a second transparent electrode on the light absorption layer.

At this time, a description of the method for manufacturing the light-transmitting solar cell according to another exemplary embodiment may include the contents substantially overlapping with the contents related to the composition for forming the hole transport layer according to the exemplary embodiment, and the description of the overlapping portion may be omitted, and in addition to the forming of the hole transport layer, the preparing of the first transparent electrode, the forming of the electron transport layer, the forming of the light absorption layer, and the forming of the second transparent electrode may be manufactured by using the technology known in the art.

The forming of the hole transport layer may include using the composition as described herein. Particularly, the forming of the hole transport layer may include performing a solution process, i.e. applying the composition as described herein (e.g., solution of the composition), on the light absorption layer by using the composition for forming the hole transport layer; and heat-treating the the applied composition.

Particularly, the applying the composition may be performed at a temperature of about 150° C. or less for about 45 seconds to 55 seconds.

For example, when applying the composition, a coating method known in the art may be used for the solution process, and for example, a spin coating, a dip coating, an inkjet printing, a gravure printing, a spray coating, a doctor blade, a bar coating, a brush painting, etc. may be used, and preferably, the application process may be performed by the spin coating, which has a high coating speed, excellent reproducibility, and enables the lamination of the uniform and dense thin film.

A temperature of the solution process may be performed at a temperature of about 150° C. or less, or particularly, performed at a temperature of about 110° C. to 130° C. When the temperature of the solution process is less than the above range, e.g., less than about 110° C., the interconnection between the hole transport material and the photoactive layer may be insufficient, leading to the degradation of device performance. When the temperature of the solution process is greater than about the above range, e.g., greater than about 150° C., a lower perovskite photoactive layer may be damaged.

In addition, the composition may be applied for about 40 seconds to 60 seconds, and particularly, for about 45 seconds to 55 seconds. When the application time is less than the above range, e.g., less than about 40 seconds, a uniform and dense thin film may not be formed. When the solution process time is greater than the above range, e.g., greater than 60 seconds, the time required for the process of manufacturing the device increases.

In addition, the heat-treating of the results of the solution process may heat-treat the results of the solution process at a temperature of about 110° C. to 130° C. for about 5 minutes to 15 minutes. When the heat treatment temperature is less than the above range, e.g., less than about 110° C., the interconnection between the hole transport material and the photoactive layer may be insufficient, leading to the degradation of device performance. When the heat treatment temperature is greater than the above range, e.g., greater than about 130° C., the lower perovskite photoactive layer may be damaged. In addition, when the heat treatment time is less than the above range, e.g., less than about 5 minutes, the single solvent is not sufficiently evaporated, and when the heat treatment time is greater than the above range, e.g., greater than about 16 minutes, the lower layer may be damaged.

In an aspect, a light-transmitting solar cell may include an n-i-p structure manufactured by the method for manufacturing the light-transmitting solar cell. The light-transmitting solar cell may include a first transparent electrode; an electron transport layer formed on the first transparent electrode; a light absorption layer formed on the electron transport layer; a hole transport layer formed on the light absorption layer; and a second transparent electrode formed on the hole transport layer.

In particular, the hole transport layer may include a metal oxide-based hole transport material, and may form a dense and uniform thin film on a perovskite light absorption layer. Therefore, there is no structural difference between the hole transport layers manufactured with the single solvent and the conventional mixed solvent, and both compositions are densely and uniformly formed on the light absorption layer, and therefore, there is no damage to the light absorption layer when the second transparent electrode is deposited.

Unlike using a mixed solvent, using the single solvent may provide uniform large-area coating. As such, the composition densely and uniformly formed on the light absorption layer may have a coverage of 90% or greater on the surface of the light absorption layer per 10 x 10 µm² unit area, and the deviation in the thicknesses of the thin film at various random points may be less than about 20%. In addition, the thickness of the hole transport layer may be about 10 nm to 200 nm. When the thickness of the hole transport layer is less than the above range, e.g., less than about 20 nm, the dense thin film may not be formed due to insufficient coverage when the thin film of the hole transport layer is formed. When the thickness of the hole transport layer is greater than the above range, e.g., greater than about 200 nm, the series resistance increases, leading to the degradation of device performance.

The hole transport layer having the large area may be obtained due to having densification and uniformity when the hole transport layer is manufactured with the composition including the single solvent at a low temperature.

The first transparent electrode is a lower electrode based on the n-i-p structure, and one having a material with conductivity doped on the flexible and transparent material such as plastic including polyethylene terephthalate (PET), polyethylene naphthalate (PEN), polypropylene (PP), polyimide (PI), polycarbonate (PC), polystyrene (PS), polyoxyethylene (POM), AS resin (acrylonitrile styrene copolymer), ABS resin (acrylonitrile butadiene styrene copolymer), triacetyl cellulose (TAC), polyacrylate (PAR), etc. in addition to a glass and a quartz plate may be used. Preferably, the first transparent electrode may include indium tin oxide (ITO), fluorine doped tin oxide (FTO), aluminum doped zinc oxide (AZO), and indium zinc oxide (IZO), ZnO-Ga₂O₃, ZnOAl₂O₃, antimony tin oxide (ATO), transparent conductive oxide (TCO), carbon nanomaterial, etc.

In addition, the first transparent electrode may further include a substrate thereunder. As the substrate, a substrate excellent in transparency, surface smoothness, handling easiness, and waterproofness may be used. Specifically, a glass substrate, a thin film glass substrate, or a plastic substrate may be used. The plastic substrate may include a flexible film such as polyethylene terephthalate (PET), polyethylene naphthalate (PEN), polyether ether ketone, and polyimide in the form of a single layer or multiple layers. However, the substrate is not limited thereto, and a substrate commonly used in the light-transmitting solar cell may be used.

The electron transport layer may transport electrons generated in the light absorption layer to the first transparent electrode, and may include a metal oxide layer, and preferably, use one or two or more selected from the group consisting of Ti oxide, Zn oxide, In oxide, Sn oxide, W oxide, Nb oxide, Mo oxide, Mg oxide, Zr oxide, Sr oxide, Yr oxide, La oxide, V oxide, Al oxide, Y oxide, Sc oxide, Sm oxide, Ga oxide, SrTi oxide, and composites thereof, but is not limited thereto.

The light absorption layer may include a compound having a perovskite structure. Particularly, the light absorption layer may include CH₃NH₃PbI₃, HC(NH₂)₂PbI₃, CH₃NH₃PbBr₃, HC(NH₂)₂PbBr₃, (CH₃NH₃)ₐ(HC(NH₂)₂)₍₁₋ₐ₎PbIzBr_{(3-z)}, or (HC(NH₂)₂)_{b}(CH₃NH₃)_{c}Cs_{d}PbI_{z}Br_{(3-z′)}, where a is a real number of 0<a<1, b is a real number of 0<b<1, c is a real number of 0<c<1, d may be a real number of 0<d<1, b+c+d may be 1, z may be a real number of 0<z<3, and z′ may be a real number of 0<z′<3.

The second transparent electrode is an upper electrode based on the n-i-p structure, and as a translucent electrode, the second transparent electrode may include a metal such as silver (Ag), gold (Au), magnesium (Mg) or an alloy thereof, but preferably, to improve light transmittance, the upper electrode may also employ the transparent electrode, and include the same or different type of material as that of the first transparent electrode.

In another aspect, the light-transmitting solar cell including the hole transport layer satisfying the above characteristics may have an advantage in that the photoelectric conversion efficiency is not reduced as the transmittance is 50% or greater even in an energy wavelength region lower than a band gap.

### EXAMPLE

The present disclosure will be described in more detail with reference to the following examples. The following examples are merely illustrative to help the understanding of the present disclosure, and the scope of the present disclosure is not limited thereto.

### Manufacturing Example 1: Manufacturing of the Composition for Forming the Hole Transport Layer of the Light-Transmitting Solar Cell

A solution of mixing 1 mmol of Ni acetylacetonate, 10 mL of oleylamine, and 10 mL of toluene, which were a metal oxide precursor, was put into a Teflon container placed in a steel autoclave, and reacted at a temperature of 180° C. for 6 hours. After cooling the steel autoclave to room temperature, the NiO nanoparticles, which were the generated metal oxide-based hole transport material, were washed with acetone and ethanol. Thereafter, the washed NiO nanoparticles were dissolved in 5 mL of hexane, and 0.1 g of sodium acetate was added thereto to be adjusted to pH6, and then they were mixed through sonication by using a sonicator for 30 minutes. Thereafter, the NiO nanoparticles were obtained through centrifugation. The obtained NiO nanoparticles were washed with acetone and then freeze-dried.

### Manufacturing Example 2: Manufacturing of the Composition for Forming the Hole Transport Layer of the Light-Transmitting Solar Cell

The composition for forming the hole transport layer was finally manufactured by dissolving the NiO nanoparticles of 30 mg, which were the metal oxide-based hole transport material obtained through Manufacturing Example 1, in 1 mL of 1-hexanol, which was the single solvent.

### Manufacturing Example 3: Manufacturing of the Composition for Forming the Hole Transport Layer of the Light-Transmitting Solar Cell

The composition for forming the hole transport layer was finally manufactured by dissolving the NiO nanoparticles of 30 mg, which were the metal oxide-based hole transport material obtained through Manufacturing Example 1, in 1 mL of 1-octanol, which was the single solvent.

### Example 1: Manufacturing of Light-Transmitting Solar Cell

The thin film of the electron transport layer was formed by washing the glass substrate (hereinafter, referred to as the FTO substrate) coated with fluorine-containing tin oxide having the size of 2.5 × 2.5 cm, which was the first transparent electrode, by using acetone, and then spin-coating the tin oxide nanoparticle solution on the washed FTO substrate under the condition of 3000 rpm.

The perovskite solution was manufactured by completely dissolving [CH(NH₂)₂PbI₃]_{0.95}[CH₃NH₃PbBr₃]_{0.05} 1.44 M in the mixed solution of dimethylformimide solution and dimethylsulfoxide solution (volume ratio 8:1). The perovskite thin film, which was the light absorption layer, was manufactured by spin-coating the perovskite solution on the previously manufactured thin film of the electron transport layer under the condition of 5000 rpm by using a non-solvent dropping method and performing the heat treatment at the temperature of 150° C. for 10 minutes.

The thin film of the hole transport layer having the thickness of 40 to 60 nm was manufactured by spin-coating and applying the composition for forming the hole transport layer of the light-transmitting solar cell obtained according to Manufacturing Example 2 on the perovskite thin film under the condition of 2000 rpm for 50 seconds, and then performing the heat treatment at a temperature of 120° C. for 10 minutes.

Then, the light-transmitting solar cell was finally manufactured by depositing and forming the ITO transparent electrode (second transparent electrode) under the conditions that the output was 200 W, the temperature was 50 degrees, the pressure was 6 mtorr, and the time was 20 minutes in the thickness of about 350 nm by using the sputter equipment.

### Example 2: Manufacturing of Light-Transmitting Solar Cell

The light-transmitting solar cell was manufactured in the same manner as in Example 1, except that the thin film of the hole-transport layer was manufactured by applying the composition for forming the hole transport layer of the light-transmitting solar cell obtained according to Manufacturing Example 3 on the perovskite.

### Comparative Example 1-1: Manufacturing of the Solar Cell Whose Upper Electrode was the Opaque Electrode

When comparing it with Example 1, the solar cell was manufactured in the same manner as in Example 1, except that the upper electrode was formed by depositing a gold electrode on the thin film of the hole transport layer in the thickness of 120 nm by using a high vacuum vaporizer (degree of vacuum 5 × 10⁻⁶ torr) instead of the second transparent electrode.

### Comparative Example 1-2: Manufacturing of the Solar Cell Whose Upper Electrode was the Opaque Electrode

When comparing it with Example 2, the solar cell was manufactured in the same manner as in Example 2, except that the upper electrode was formed by depositing a gold electrode on the thin film of the hole transport layer in the thickness of 120 nm by using the high vacuum vaporizer (degree of vacuum 5 × 10⁻⁶ torr) instead of the second transparent electrode.

### Comparative Example 2-1: Manufacturing of the Light-Transmitting Solar Cell Including the Hole Transport Layer Including the Organic Material

When comparing it with Example 1, the solar cell was manufactured in the same method as in Example 1, except that a Spiro-OMeTAD solution (solvent: chlorobenzene) with the concentration of 90 g/L was applied and spin-coated at 2000 rpm for 30 seconds to form the hole transport layer on the perovskite layer, which was the light absorption layer.

### Comparative Example 2-2: Manufacturing of the Solar Cell Including the Hole Transport Layer Including the Organic Material and the Upper Electrode that was the Opaque Electrode

When comparing it with Comparative Example 2-1, the solar cell was manufactured in the same manner as in Comparative Example 2-1, except that the upper electrode was formed by depositing a gold electrode on the thin film of the hole transport layer in the thickness of 120 nm by using the high vacuum vaporizer (degree of vacuum 5 × 10⁻⁶ torr) instead of the second transparent electrode.

### Comparative Example 3-1: Manufacturing of the Light-Transmitting Solar Cell Including the Hole Transport Layer Including the Organic Material

When comparing it with Example 1, the solar cell was manufactured in the same method as in Example 1, except that a PTAA solution (solvent: chlorobenzene) with the concentration of 20 g/L was applied and spin-coated at 2000 rpm for 30 seconds to form the hole transport layer on the perovskite layer, which was the light absorption layer.

### Comparative Example 3-2: Manufacturing of the Solar Cell Including the Hole Transport Layer Including the Organic Material and the Upper Electrode that was the Opaque Electrode

When comparing it with Comparative Example 3-1, the solar cell was manufactured in the same manner as in Comparative Example 3-1, except that the upper electrode was formed by depositing a gold electrode on the thin film of the hole transport layer in the thickness of 120 nm by using the high vacuum vaporizer (degree of vacuum 5 × 10⁻⁶ torr) instead of the second transparent electrode.

### Experimental Example 1: Analysis of the Current Density and Transmittance of the Light-Transmitting Solar Cell

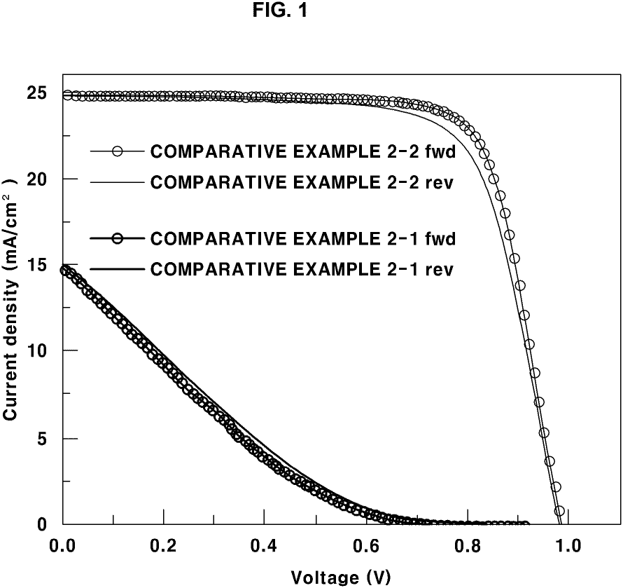

After manufacturing the solar cells according to Manufacturing Examples 1 to 3, Examples 1 and 2, and Comparative Examples 1-1 to 3-2, the results of analyzing the photoelectric conversion properties, transmittance, and the characteristics of the composition of the hole transport layer according to the light scan direction were shown in Table 1 and FIGS. 1 to 7.

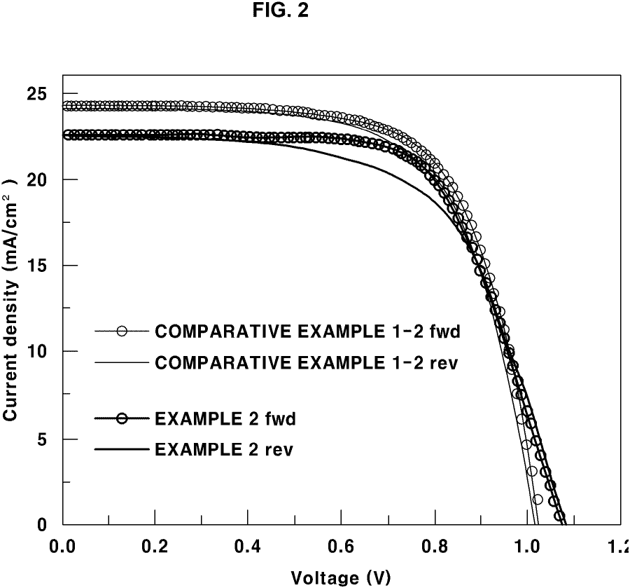

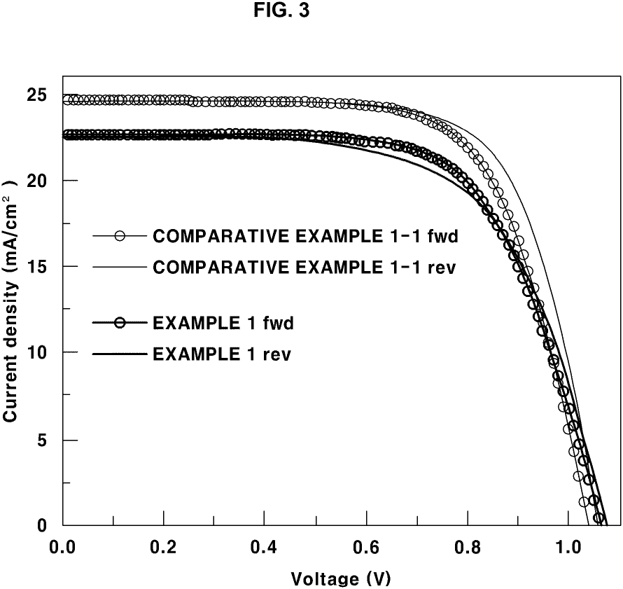

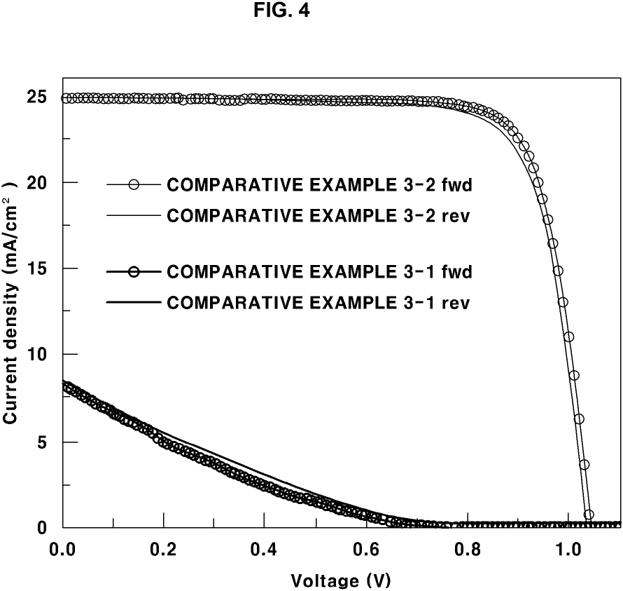

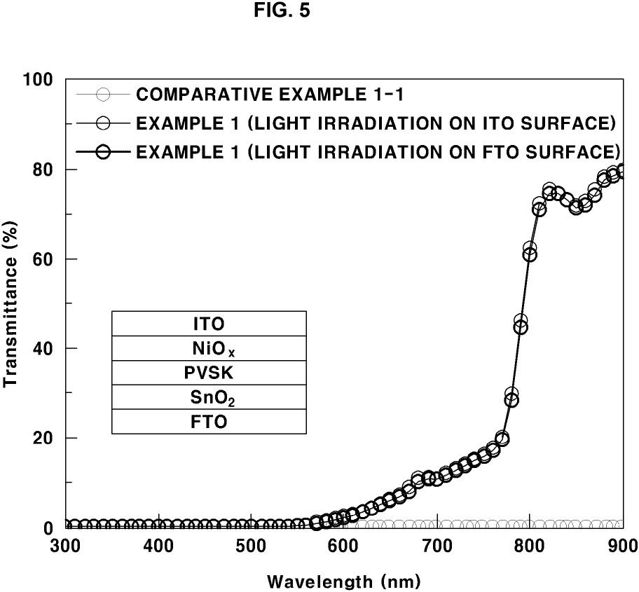

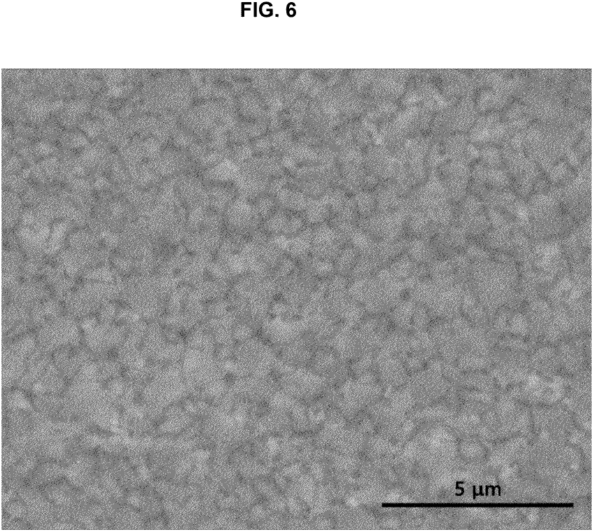

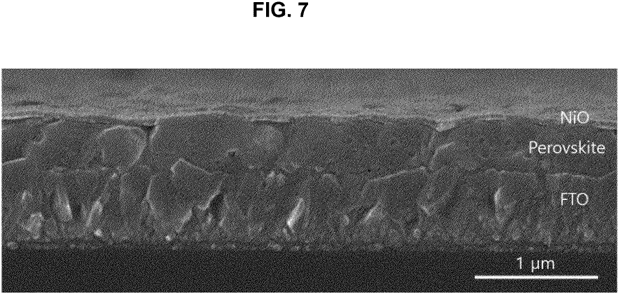

As shown in, FIG. 1 was a graph showing a current density-voltage curve according to light scan directions (forward vs. reverse) of solar cells according to Comparative Examples 2-1 and 2-2, FIG. 2 was a graph showing a current density-voltage curve according to light scan directions (forward vs. reverse) of solar cells according to Example 2 and Comparative Example 1-2, FIG. 3 was a graph showing a current density-voltage curve according to light scan directions (forward vs. reverse) of solar cells according to Example 1 and Comparative Example 1-1, and FIG. 4 was a graph showing a current density-voltage curve according to light scan directions (forward vs. reverse) of solar cells according to Comparative Examples 3-1 and 3-2. FIG. 5 was a graph showing transmittance measurement results of the solar cells according to Example 1 and Comparative Example 1-1. In addition, FIG. 6 was a plan view of a scanning electron microscope (SEM) showing a surface coverage of a light absorption layer of a hole transport layer finally manufactured with the composition produced according to Manufacturing Example 2, and FIG. 7 was a cross-sectional view of a scanning electron microscope (SEM) showing a thin film thickness (uniformity) of the hole transport layer finally formed on the light absorption layer with the composition produced according to Manufacturing Example 2.

TABLE 1

| Items | Scan direction | Photo short-circuit current density (J_{sc,} mA/cm²) | Photo open-circuit voltage (V_{oc,} V) | Fill factor (%) | Photoelectric conversion efficiency (PCE, %) |
|---|---|---|---|---|---|
| Comparative Example 1-1 | Forward | 24.58 | 1.04 | 68.68 | 17.56 |
| | Reverse | 24.48 | 1.06 | 70.52 | 18.30 |
| Comparative Example 1-2 | Forward | 24.35 | 1.03 | 66.94 | 16.79 |
| | Reverse | 24.30 | 1.02 | 65.10 | 16.14 |
| Example 1 | Forward | 22.60 | 1.06 | 66.49 | 15.93 |
| | Reverse | 22.53 | 1.07 | 64.09 | 15.45 |
| Example 2 | Forward | 22.58 | 1.07 | 66.51 | 16.07 |
| | Reverse | 22.55 | 1.08 | 61.32 | 14.93 |
| Comparative Example 2-2 | Forward | 24.81 | 0.98 | 75.13 | 18.27 |
| | Reverse | 24.61 | 0.98 | 71.73 | 17.30 |
| Comparative Example 2-1 | Forward | 14.83 | 0.71 | 18.52 | 1.95 |
| | Reverse | 15.13 | 0.74 | 18.89 | 2.12 |
| Comparative Example 3-2 | Forward | 24.82 | 1.04 | 79.08 | 20.41 |
| | Reverse | 24.63 | 1.03 | 78.32 | 19.87 |
| Comparative Example 3-1 | Forward | 8.25 | 0.82 | 16.25 | 1.10 |
| | Reverse | 8.18 | 0.87 | 17.95 | 1.28 |

As shown in Table 1 and FIGS. 1 to 5, the light-transmitting solar cells manufactured according to Examples 1 and 2 showed the transmittance of 80% or more and the photoelectric conversion efficiency of 15 % or greater by depositing the transparent electrode on the lower layer without damage in the transparent electrode sputter deposition process. The light-transmitting solar cells manufactured according to Comparative Examples 2-1 to 3-1, the light was transmitted, but the photoelectric conversion efficiency was very low and the solar cells were not normally driven due to damage to the lower layer in the transparent electrode deposition process.

As shown in FIGS. 6 to 7, the hole transport layer finally manufactured with the composition prepared according to Manufacturing Example 2 had the coverage of 90% or greater on the surface of the light absorption layer per unit were a, and the thicknesses of the thin film at various random points were less than 20%, and the dense and uniform hole transport layer to prevent damage to the lower layer in the subsequent transparent electrode sputter deposition process was formed on the light absorption layer.

### Experimental Example 2: Performance Analysis of the Solar Cell According to theType of Solvent

As shown in Table 1, it was confirmed that all of the light-transmitting solar cells manufactured according to Examples 1 and 2 have the transparent electrode deposited on the lower layer without damage in the transparent electrode sputter deposition process to maintain the photoelectric conversion efficiency of 15% or greater in average. In addition, the light-transmitting solar cell had no significant difference in device performance even if two different single solvents were used as the composition for forming the hole transport layer.

While the exemplary embodiments of the present disclosure have been described above with reference to the accompanying drawings, those skilled in the art to which the present disclosure pertains will be able to understand that the present disclosure may be practiced in other specific forms without changing its technical spirit or essential features. Therefore, it should be understood that the aforementioned exemplary embodiments are illustrative and not restrictive in all respects.

What is claimed is:

1. A composition for forming a hole transport layer of a light-transmitting solar cell comprising:
a metal oxide-based hole transport material; and
a solvent component.

2. The composition of claim 1, wherein the metal oxide-based hole transport material comprises one selected from the group consisting of a nickel oxide-based hole transport material, a copper oxide-based hole transport material, a vanadium oxide-based hole transport material, a chromium oxide-based hole transport material, and a tungsten oxide-based hole transport material.

3. The composition of claim 2, wherein the metal oxide-based hole transport material comprises one or more selected from the group consisting of NiOₓ (1≤x≤2), Cu₂O, CuO, CuGaO₂, CuCrO₂, VO₂, CrO₂, and WO₃.

4. The composition of claim 1, wherein the single solvent comprises one selected from the group consisting of alcohols in which a hydrogen bonding index is 13 MPa^{½} or less and the number of carbon atoms of an alkyl group is 6 or more.

5. The composition of claim 4, wherein the alcohols comprises one selected from the group consisting of hexanol, heptanol, octanol, nonanol, decanol, undecanol, dodecanol, tetradecanol, pentadecanol, hexadecanol, and octadecanol.

6. The composition of claim 1, wherein the concentration of the composition for forming the hole transport layer of the light-transmitting solar cell is 1 mg/mL to 100 mg/mL.

7. A light-transmitting solar cell, comprising a hole transport layer formed from the composition of claim 1.

8. A method for manufacturing a light-transmitting solar cell, comprising:
preparing a first transparent electrode;
forming an electron transport layer on the first transparent electrode;
forming a light absorption layer comprising a compound having a perovskite structure on the electron transport layer;
forming a hole transport layer on the light absorption layer comprising a composition comprising a metal oxide-based hole transport material and a solvent component; and
forming a second transparent electrode on the light absorption layer.

9. The method of claim 8, wherein the forming of the hole transport layer comprises:
applying the composition on the light absorption layer; and
heat-treating the applied composition.

10. The method of claim 8, wherein the forming of the hole transport layer is performed at the temperature of about 150° C. or less for about 45 seconds to 55 seconds.

11. The method of claim 8, wherein the heat-treating the applied composition is performed at the temperature of about 110° C. to 130° C. for about 5 minutes to 15 minutes.

12. A light-transmitting solar cell comprising:
a first transparent electrode;
an electron transport layer formed on the first transparent electrode;
a light absorption layer formed on the electron transport layer;
a hole transport layer formed on the light absorption layer; and
a second transparent electrode formed on the hole transport layer,
wherein the hole transport layer comprises a metal oxide-based hole transport material, and the composition densely and uniformly formed on the light absorption layer has a coverage of about 90% or greater on the surface of the light absorption layer per 10 × 10 µm² unit area, and the deviation of the thicknesses of the thin film at various random points are less than about 20%.

13. The light-transmitting solar cell of claim 12,
wherein the thickness of the hole transport layer is about 10 nm to 200 nm.

14. The light-transmitting solar cell of claim 12,
wherein a transmittance is about 50% or greater.

15. A vehicle comprising a light-transmitting solar cell of claim 12.
